(19) United States
(12) Patent Application Publication
(10) Pub. No.: US 2024/0215170 A1
(43) Pub. Date: Jun. 27, 2024

(54) ELECTRONIC MODULE AND CONTACT ARRANGEMENT

(71) Applicant: Robert Bosch GmbH, Stuttgart (DE)

(72) Inventor: Irfan AYDOGMUS, NUERTINGEN (DE)

(21) Appl. No.: 18/542,843

(22) Filed: Dec. 18, 2023

(30) Foreign Application Priority Data
Dec. 21, 2022 (DE) 10 2022 214 174.1

(51) Int. Cl. H05K 1/18; H01R 12/52; H01R 12/58

(52) U.S. Cl. CPC H05K 1/186; H01R 12/52; H01R 12/58; H05K 2201/09754; H05K 2201/10189

(57) ABSTRACT

An electronic module. The electronic module includes a circuit carrier having an electrical and/or electronic circuit. This circuit is completely embedded in an encapsulation molding compound. The electronic module includes an electrically contactable outer contact connection arranged on the enclosure, which has a press-fit zone. The contact connection is electrically connected to the electrical and/or electronic circuit on an upper side of the circuit carrier facing the press-fit zone. In the region of the press-in zone, the contact connection in the enclosure is free of the encapsulating compound. The contact connection is accommodated in a cavity of a holding frame made of a plastics material. The cavity is formed by a closed wall running around the contact connection, which rests on the upper side of the circuit carrier and projects in a direction of the press-fit zone. The wall separates the cavity from the encapsulating compound.

### CROSS REFERENCE

The present invention relates to an electronic module, a contact arrangement comprising the electronic module, and a method for forming the electronic module.

### BACKGROUND INFORMATION

Many electronic devices have an external contact connection for contacting further electrical components and/or electrical devices. The need for such contact connections is varied. For example, a supply of power is often secured via an external contact connection. In addition, in some applications the electronic device is functionally set up to receive, process, and/or send data signals, and then uses an external contact connection for data communication. It is also possible to put together a complete electrical system from individual electrical and/or electronic sub-assemblies in a final assembly stage. Available external contact connections then serve as joining interfaces for forming the overall electrical system by means of connecting lines, for example.

External contact connections are often provided in the form of plug connectors. In automotive applications, so-called male multipoint connectors are often used to meet high electrical and mechanical requirements, which have, within a plug connector body, plug pins for a complementary mating connector according to a connection schema. At their end, the plug pins have press-fit pins, which in turn make electrical contact between the male multipoint connector and an electrical circuit on a circuit carrier. Male multipoint connectors of this type are very expensive, so that simple contact elements which in electrical contact with the electrical circuit are also provided for simple and/or less frequently required contact connections.

A semiconductor device embedded in a molding compound is described in German Patent Application No. DE 10 2014 211 698 A1. Upper-side connection surfaces of the semiconductor device are routed out of the molded body by means of sleeves and are then available as external contact connections. The semiconductor component can then be electrically contacted by other electrical components via corresponding plug contacts. The sleeves are in each case individually connected to one of the upper-side connection surfaces of the semiconductor component by means of a solder connection. If there are several sleeves as the contact connections, these must have a high degree of positional accuracy in relation to each other in order to ensure contactability, for example for a mating connector.

German Patent Application No. DE 10257032 A1 shows the production of a sensor chip. Here the sensor chip is packaged in a plastic housing that is manufactured using an injection-molding process. After packaging, the plastic housing is opened in the area of the sensor element using a laser and is exposed by the material of the plastic housing.

### SUMMARY

An object of the present invention including making inexpensive and flexibly scalable contact connections possible in electronic modules which are enclosed in particular with an encapsulating compound.

This object may be achieved by an electronic module, a contact arrangement comprising the electronic module, and a method for forming the electronic module according to features of the present invention.

The present invention is based on an electronic module comprising a circuit carrier having an electrical and/or electronic circuit. According to an example embodiment of the present invention, this circuit is completely embedded in an encapsulating compound, in particular a molding compound, forming an enclosure of the electronic module. The electronic module further comprises at least one electrically contactable outer contact connection arranged on the enclosure, which has at least one press-fit zone. The contact connection is electrically connected to the electrical and/or electronic circuit on an upper side of the circuit carrier facing the press-fit zone. At least in the region of the press-in zone, the contact connection in the enclosure is free of the encapsulating compound. The contact connection is accommodated in a cavity of a holding frame, in particular made of a plastic material, wherein the cavity is formed by a closed wall running around the contact connection. Here the wall rests on the upper side of the circuit carrier and projects from the upper side of the circuit carrier in the direction of the press-fit zone. The wall here separates the cavity from the encapsulating compound. The holding frame advantageously acts as a protective barrier, whereby the contact connection does not come into direct contact with an encapsulating compound. In particular if the enclosure is formed by means of an injection-molding process, the contact connection can be partitioned off by means of the holding frame from possible mechanical damage due to the forces prevailing here during the injection of the molding compound at high pressure.

This results overall in a simpler production process with a significantly reduced reject rate. This is also because incorrectly adhering encapsulating compound in a contact region, which, including the press-fit zone, is designed as an external connection option for the electronic module for direct contacting, can therefore be ruled out. The connection of the contact connection to the circuit carrier also needs to be designed with less mechanical strength, which means that the contact connections themselves can be kept small. Preferably, the wall of the holding frame on the side facing away from the top of the circuit carrier extends at most as far as an outer surface of the enclosure. The holding frame preferably has interlocking structures in an overlapping region with the encapsulating compound, which increases the bonding of the holding frame within the enclosure. The interlocking structures can be formed as recesses or projecting structural elements, in particular on an outer lateral surface of the wall of the holding frame.

Advantageous developments and improvements of the plug connector according to the present invention are made possible by the measures disclosed herein.

In an advantageous embodiment of the electronic module of the present invention, the holding frame has at least two, three or more cavities. These are arranged in particular directly adjacent to one another and are separated from one another by a common wall web within the holding frame. At least or exactly one contact connection is accommodated in each of these cavities, forming a defined connection schema of the electronic module. This makes it easy to implement connection schemas that are also common in plug connector systems. Preferably, the connection schema comprises at least two, three, or more press-fit zones configured in a linear arrangement and/or in a circular arrangement. This also provides a high degree of flexibility to provide scalable connection options for different designs and/or applications by implementing them with the number of required press-fit zones. For this purpose, the holding frame can be adapted accordingly, for example using a few standardized modular elements. In particular, the modular elements can be connected to each other for example using a plug-in system, snap-in connections, or other means. A plurality of interconnected modular elements thus forms the correspondingly required holding frame. Alternatively, the modularity is shifted to an injection-molding tool provided for the production of the holding frame, so that a holding frame with a one-piece construction can be adapted to the need for the required connection option by means of corresponding changeable tools and/or changing tool modules. Here the contact connection can be designed as a common part in the connection schema. Using the holding frame, however, it is also possible to design at least two contact connections differently, as long as the size of the cavity of a standardized holding frame is sufficient to accommodate the differently designed contact connections with no collisions.

Advantageously, the design of the electronic module according to the present invention also allows a high degree of flexibility in the way in which a connecting foot of the contact connection is ultimately contacted with the upper side. Possible and preferred electrical contact connections for the connection foot are soldered, sintered, glued or press-fit contacts. In principle, the aforementioned electrical contact connections are also made possible in a holding frame in which the cavity in the wall end region facing the upper side is closed by an integrally formed base region that extends up to the wall. In these cases, the contact connection in the region of the connecting foot penetrates through the base region of the holding frame and thereby furthermore provides one of the mentioned contact connections. The base region reinforces a barrier against the penetration of the encapsulating compound into the cavity during the formation of the housing by means of an injection-molding process.

In a particularly favorable embodiment of the electronic module of the present invention, the holding frame is designed as a positioning aid for the defined positioning of all accommodated contact connections relative to the upper side of the circuit carrier and/or, in the case of two or more contact connections, for defined positioning relative to one another. This is achieved, for example, in that inner lateral surfaces of the wall regions of the holding frame have defined limiting stops in the region of the cavity in question. These limiting stops restrict the positioning of all accommodated contact connections at least in the direction of the lateral extension of the upper side of the circuit carrier. As cavities are designed individually and geometrically relative to each other within an adapted tolerance range, the designed connection schema can be ensured with a dimensional accuracy that is still within tolerance even with the most unfavorable positioning of all contact connections within a given cavity, due to the defined limited positioning by the limiting stops. Once the dimensions of a tooling-dependent holding frame have been reduced, then, in the case of plurality of contact connections, an otherwise required precise positioning and checking of the position of each individual contact connection in order to form a dimensionally correct contact schema can be dispensed with. A position of the holding frame in relation to the circuit carrier can be easily achieved with precision by providing positioning elements on the holding frame and on the circuit carrier that are complementary to each other, which in interaction determine the position of the holding frame on the upper side of the circuit carrier. A positioning dome can thus project from the holding frame, in particular perpendicular to the upper side, said positioning dome engaging in a complementary recess in the circuit carrier. Alternatively, the holding frame can be bonded to the upper side of the circuit carrier by means of an adhesive layer. It is also possible for the holding frame to be hot-caulked in a contact region with the upper side in such a way that, due to the caulking by means of a tool, a plastic material that is at least briefly softened and displaced towards the upper side forms a material bond with the upper side when it cools again.

In a preferred embodiment of the electronic module of the present invention, the contact connection also has a flexible region, in particular between a region of connection with the upper side and the press-fit zone. When a force is applied to the press-fit zone of the contact connection, in particular when the electronic module makes electrical contact with at least one connecting line of another electronic module or an electrical component, the contact connection is designed to be flexible at least in the direction of the upper side due to the flexible region. The flexibility is limited in its travel in particular by a limiting stop that is then also integrally formed in the holding frame. Due to the flexibility, plug-in forces can be kept within a permissible range, making possible a contacting but not exerting excessive mechanical force on the electronic module.

In an alternative embodiment of the electronic module of the present invention, the opening into the cavity formed by a wall end region of the holding frame on the side of the holding frame facing away from the upper side is closed by a contact region of the contact connection having the press-fit zone, in that the contact region rests on the edge of the wall end region. The electrical and mechanical contacting of the contact connection in the region of the press-fit zone is therefore made in particularly rigid fashion. This is particularly suitable for applications in which high retaining forces are required after forming a press-fit contact with the aforementioned connecting line, for example to prevent the connecting line from detaching until the corresponding retaining force is reached.

In an advantageous further development of the electronic module of the present invention, complementary latching elements are formed on the holding frame and the contact connection. A latching connection is formed between the latching elements in such a way that the holding frame is held between the latching connection and the upper side of the circuit carrier, in particular in a force-loaded manner, in particular in a clamping manner. Here a spring element integrally formed on the contact connection can be supported on a support region of the holding frame after a contact connection has been formed between the connection foot and the upper side of the circuit carrier, and in doing so can be elastically deformed to such an extent that a spring force acting in particular in the direction of the upper side is in effect.

Generally advantageously, according to an example embodiment of the present invention, the contact connection is formed from in particular a shaped sheet metal part, preferably in one piece.

In this way, contact connections of this type that are already commercially available can be used, providing inexpensive realizations of the electronic module. It is also possible to provide individually adapted contact connections and to adapt the connection option to a specific application.

A particularly simple and reliable embodiment of the electronic module according to the present invention results from the press-fit zone being a recess, in particular a circular hole, which is made complementary to a press-fit head of a press-fit pin to be pressed into the recess. Press-fit contacts of this type are particularly attractive for mass production or series production, as they can be handled very easily and reliably by existing production processes. An inverse design is also possible, in which the press-fit zone on the contact connection has a press-fit head that can be pressed into a complementary recess in a connecting line.

The present invention also provides a contact arrangement comprising an electronic module according to at least one of the embodiments described above and a connecting line, which is electrically contacted with the contact connection of another electronic module or of an electrical component outside the electronic module. A press-fit contact is formed between the connection line, in particular a press-fit pin, and the press-fit zone of the contact connection, in particular a recess made complementary to the press-fit pin.

Furthermore, the present invention also provides a method for forming an electronic module according to at least one of the embodiments described above. According to an example embodiment of the present invention, with the following method steps:
a) providing the circuit carrier,
b) arranging the at least one external contact connection of the electronic module on the upper side of the circuit carrier and connecting the same electrically to the electrical and/or electronic circuit, for example forming a soldered, sintered, glued or press-fit contact,
c) forming an assembly subgroup by arranging the holding frame on the circuit carrier in such a way that a wall end region facing the upper side rests on the circuit carrier and the contact connection is accommodated within the cavity formed by a closed circumferential wall of the holding frame, so that a wall end region facing away from the upper side and a contact region, comprising the press-fit zone, of the contact connection project from the circuit carrier,
d) forming an enclosure of the electronic module by means of an injection-molding process by arranging the assembly subgroup within an injection-molding tool forming the enclosure, injecting an injectable encapsulating material into the injection-molding tool, in particular a molding material, with molding of the enclosure and complete embedding of the electrical and/or electronic circuit within the encapsulating material, demolding with subsequent solidification of the enclosure, wherein
i. the holding frame is completely covered by the encapsulating compound up to over its wall end region facing away from the upper side and the contact region of the contact connection comprising the press-fit zone, and at least the press-fit zone is subsequently exposed from the encapsulating compound in the solidified enclosure by a removal process, in particular a laser removal process, or alternatively
ii. wherein the holding frame is covered by the encapsulating compound at most up to its wall end region facing away from the upper side, whereby the contact connection is kept free of the encapsulating compound at least in the contact region comprising the press-fit zone.

In a particularly advantageous embodiment of the method of the present invention, in the function of the holding frame as a positioning aid for all contact connections to be accommodated, method step c) is carried out before method step b), wherein the positioning of all contact connections then accommodated in the respective cavity is restricted at least in the direction of the lateral extension of the upper side of the circuit carrier by limiting stops defined in wall regions of the holding frame.

According to an example embodiment of the present invention, it is particularly advantageous if the contact region or the press-fit zone of the at least one contact connection is covered or closed by a closure element before process step d) in order to prevent the direct penetration of the encapsulating material into the press-fit zone or the cavity, the closure element being removed again during or after process step d). If the press-fit zone is designed as a recess, the closure element will be designed, for example, as a shape-matched closure element inserted into the recess in a complementary manner, in particular with a support head at the end of the recess. The closing element is in particular made of a plastics material. Particularly in the case of a plurality of contact connections, it is also possible to alternatively provide a uniform auxiliary element in addition to individual closing elements, on which a number of closing elements with the same number of recesses is integrally formed.

A particularly favorable embodiment of the method of the present invention is that a latching connection is formed by accommodating the at least one contact connection in the cavity of the holding frame, whereby the contact connection is held within the holding frame or the holding frame is held between the circuit carrier and the contact connection, in particular in a force-loaded or clamping manner. Alternatively, in method step c) the holding frame can be connected to the upper side by means of an adhesive or the holding frame can be connected to the circuit carrier by hot-caulking.

In general, the same advantages already mentioned above for the electronic module of the present invention can be adduced for the method according to the present invention.

### BRIEF DESCRIPTION OF EXAMPLE EMBODIMENTS

Further advantages, features and details of the present invention can be found in the following description of preferred embodiments of the present invention and with reference to the figures.

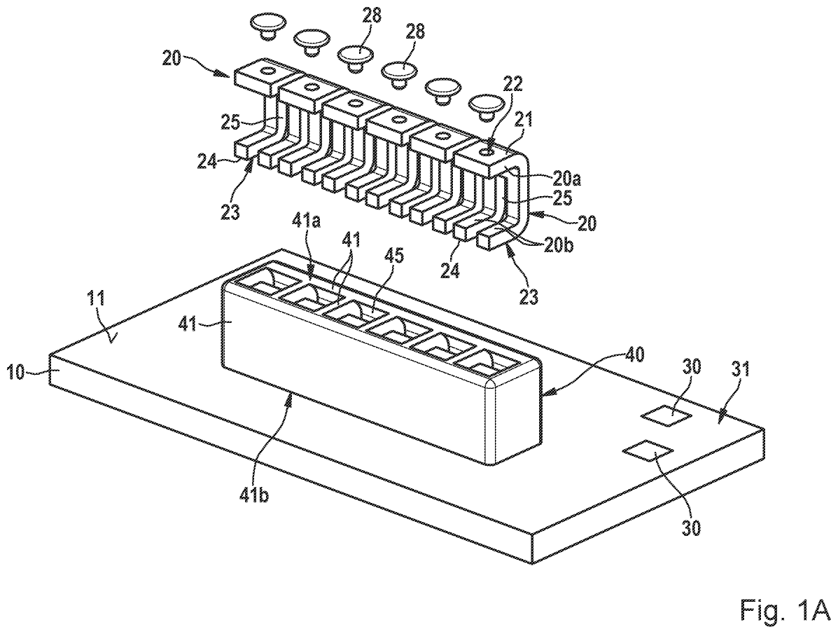

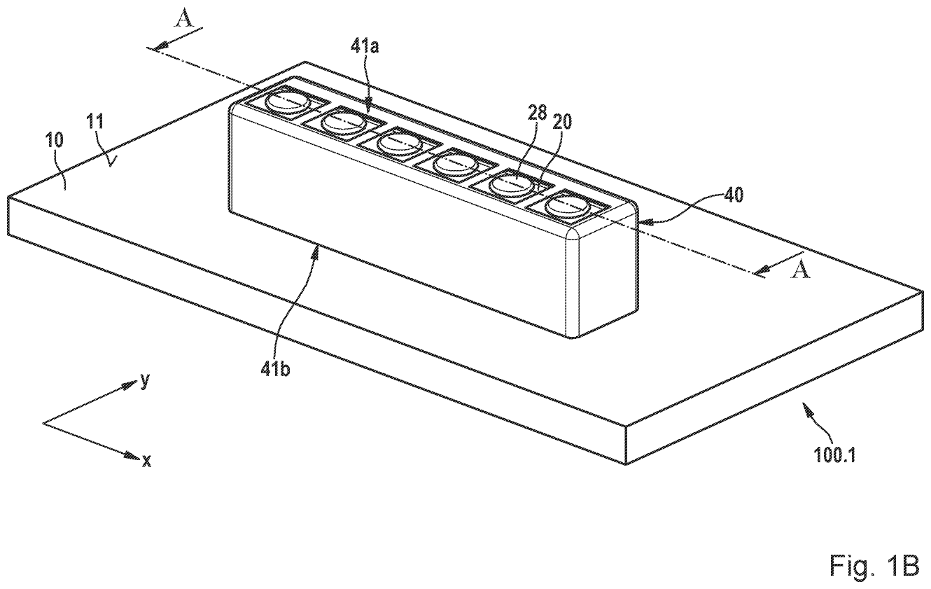

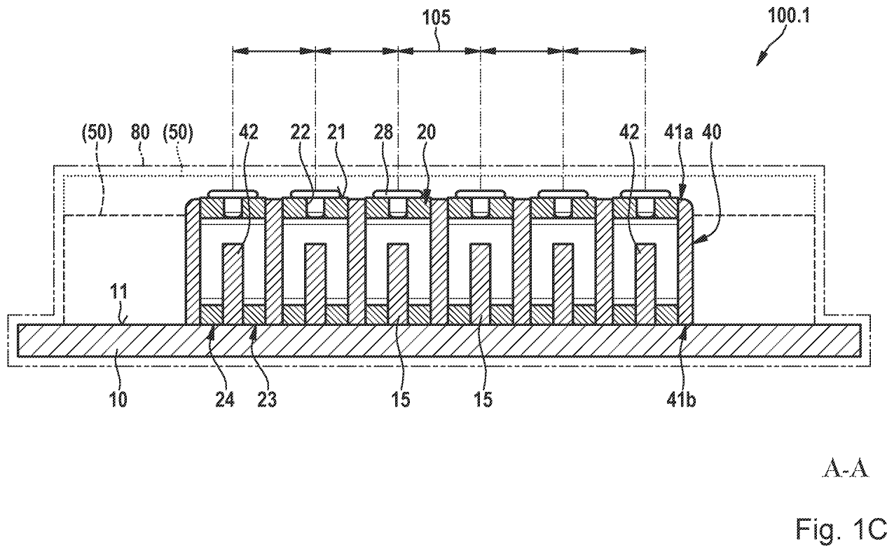

FIG. 1A shows a perspective view of components of an electronic module at the beginning of its manufacture, according to an example embodiment of the present invention.

FIG. 1B shows a perspective view of a assembly subgroup during the manufacture of the electronic module according to an example embodiment of the present invention.

FIG. 1C shows a sectional view of the assembly subgroup from FIG. 1B before or during the formation of an enclosure of the electronic module, according to an example embodiment of the present invention.

FIG. 1D shows a perspective view of the electronic module after the formation of an enclosure, according to an example embodiment of the present invention.

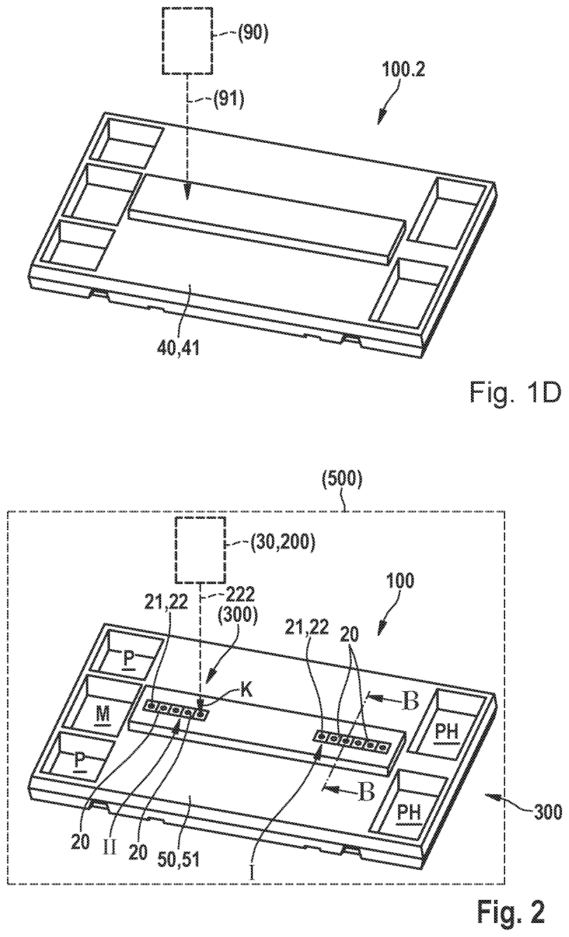

FIG. 2 shows a perspective view of the electronic module with contact connections exposed by encapsulating compound, according to an example embodiment of the present invention.

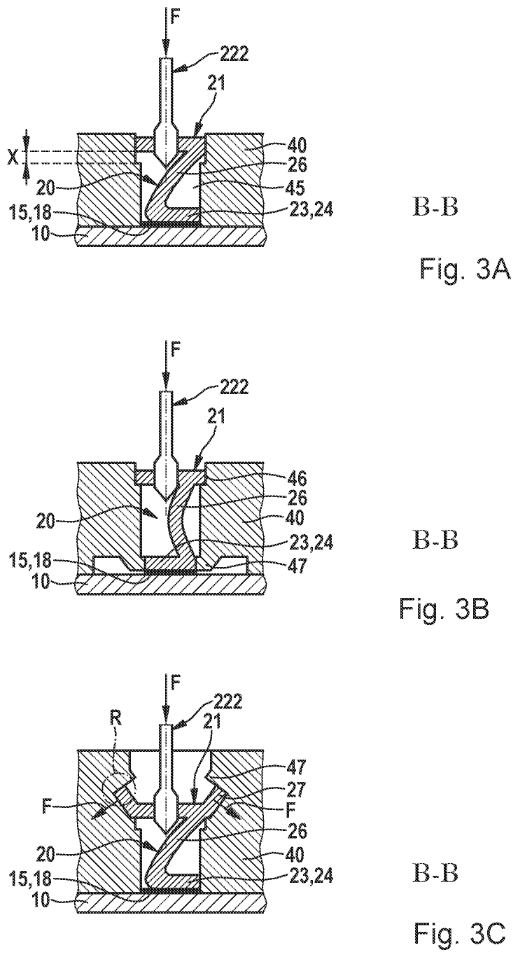

FIG. 3A shows a sectional view of a detail of the electronic module from FIG. 2 in the region of the contact connection, in a first example embodiment of the present invention.

FIG. 3B shows a sectional view of a detail of the electronic module from FIG. 2 in the region of the contact connection, in a second example embodiment of the present invention.

FIG. 3C shows a sectional view of a detail of the electronic module from FIG. 2 in the region of the contact connection, in a third example embodiment of the present invention.

### DETAILED DESCRIPTION OF EXAMPLE EMBODIMENTS

In the figures, functionally identical components are each denoted by the same reference signs.

FIG. 2 is a perspective view of an electronic module 100. An included circuit carrier 10 (not visible) with an electrical and/or electronic circuit is covered over by a solidified encapsulating compound 51. The encapsulating compound 51 forms an enclosure 50 of the electronic module 100 that is mechanically stable and that protects it from the effects of external media. On one connection side of the electronic module 100, at least one, two, or more contact connections 20 are provided exposed by the encapsulating compound 51. By means of these contact connections 20, the electronic module 100 or the electrical circuit 31 can be put into electrical contact from the outside with a connection line 220 of a further electronic module 200 and/or with a connection line 222 of an electrical component 30 outside the electronic module 100, for example a capacitor or a power supply. In the present exemplary embodiment, two contact groups I, II at a distance from each other are shown, each comprising at least one contact connection 20. Alternatively, applications can also provide only one contact group I or more than two contact groups I, II. Furthermore, a contact group I, II is designed such that a plurality of contact connections 20 is formed in a linear arrangement, wherein individual contact connections 20 are electrically insulated from one another and each have exactly one or at least one press-fit zone 22 in a respectively exposed contact region 21 of the contact connections 20. The press-fit zone 22 is preferably a defined recess, in particular a circular recess, which is made complementary to a press-fit pin of an external electrically contactable connection line 222. The press-fit zone 22 and a press-fit pin of a connecting line 222 then pressed into the press-fit zone 22 form a press-fit contact K, whereby a contact arrangement 300 is provided overall. Alternatively, the embodiment is also possible in inverse form, i.e. the contact region 21 of the contact connection 20 has a press-fit pin as the press-fit zone 22, which can be pressed accordingly into a complementary recess of a connection line 222. In principle, at least one or more formed contact groups I, II can have a plurality of contact connections 20 which are configured in a circular arrangement. Individual, multiple or all contact groups I, II can also have a plurality of rows of contacts offset to one another (not shown).

The electronic module 100 shown is, for example, a power module, in particular comprising at least one B2 or B6 bridge of power semiconductor components. In such an embodiment, the electronic module 100 has further external connections, with potential connections P, M being provided at the edge for the module power supply. Phase connections PH of the contained bridge circuit are arranged opposite also on the edge. These connections P, M, PH can be electrically contacted by soldering or welding, for example. The contact connections 20, in turn, are for example control signal connections of the bridge circuit and are electrically contacted with a control circuit 200. The power module 100 is in particular part of an inverter 500. In addition to the power module, other variant embodiments of the electronic module 100 are also possible in which, if necessary, further connections are also formed which, together with the contact connections 20, are designed differently and with different functionality.

FIG. 1A shows a perspective view of the required components of the electronic module 100 at the start of its manufacture. A circuit carrier 10 is provided at the start of the manufacturing process. The circuit carrier 10 comprises at least electrical and/or electronic components 30, which form the electrical circuit 31 of the electronic module 100 via a layout of a conductor structure. Furthermore, a corresponding number of contact connections 20, as well as closure elements 28, in particular corresponding to the number of contact connections 20 or the press-fit zones 22 formed in the contact connections 20, and a holding frame 40 are provided as required. The holding frame 40 has a plurality of cavities 45 for accommodating the contact connections 20 in each case. The cavities 45 are each formed by closed circumferential walls 41. All cavities 45 are arranged adjacent to one another in a linear arrangement, wherein a common wall 41, as an intermediate web, separates two adjacent cavities 40 from one another. All separating webs are in turn enclosed by the remaining walls 41 as frame walls, forming the holding frame 40. The cavities 45 are open on two opposite sides of the respective wall end regions 41a, 41b.

For illustrative purposes only, the contact connection 20 is shown here, only as an example, in a U-shaped design. Two legs 20a, 20b are formed opposite each other. One of the legs 20a is provided as contact region 21 of the contact connection 20 and has the press-fit zone 22 as a circular recess. The other leg 20b and a section region of the connecting central web are divided into two, so that two contact feet 23, 24 are formed in each case for making electrical contact with an upper side 11 of the circuit carrier 10. The slot 25 formed between the contact feet 23, 24 and the section region is designed to be aligned in centered fashion by a central web 42 arranged centrally between two separating webs 41 in the cavity 45 of the holding frame 40.

FIG. 1B shows a later time in the manufacturing process. Here not only the contact feet 23, 24 of all contact connections 20 but also the one wall end region 41b of the holding frame are arranged on the upper side 11 of the circuit carrier 10. Here the contact connections 20 are each accommodated in the cavities 45 formed in the holding frame 40. Not only the other wall end section 41a of the holding frame 40 but also the respective contact region 21 of the contact connections 20 then project away from the upper side 11 of the circuit carrier 10. The holding frame 40 is preferably used as a positioning aid, in that wall regions, such as the intermediate webs 41 and/or the center webs 42, as mechanical limiting stops, permit a limited, defined positioning of the contact connections 20 within the cavities 45, in particular in the direction of the lateral extension x, y of the upper side 11. In the function of the positioning aid, the contact connections 20 are positioned with a very small dimensional tolerance in relation to each other and opposite contact points 15 on the upper side 11 of the circuit carrier 10. The contact feet 23, 24 are put into electrical contact with the corresponding contact points 15, and thus with the electrical circuit 31, in particular by means of a soldered, sintered or electrically conductive adhesive layer 18. At the same time, the connection schema 105 of the electronic module 100 is thereby determined. Overall, up to this point in the manufacturing process an assembly subgroup 100.1 of the electronic module 100 is thus formed. Even before the enclosure 50 is formed in a next method step, the press-fit zones 22 and preferably also the relevant contact region 21 are covered over or closed by corresponding closing elements 28. In the case of a recess as the press-fit zone 22, a closure element 28 has a closure dome which engages in the recess in a closing manner. In addition, the closure element 28 can also have a closure head, which then rests on the contact region 21 and covers it substantially over its entire surface. The closure elements 28 are made of a plastics material, for example. In general, it is also possible to provide only one closure element 28, which covers all contact regions 21 and press-fit zones 22 in one piece. In particular, closure domes corresponding to the number of press-fit zones 22 can be integrally formed on the one closure element 28 corresponding to the distances between the press-fit zones 22.

If the holding frame 40 is not used as a positioning aid, it is also possible to first connect the contact connections 20 to the upper side 11 and then to guide the holding frame 40 over the connected contact connections 20 until it rests on the upper side 11 and the contact connections 20 are accommodated in the cavities 45. For such a sequence, there must be no elements in the joining path that prevent joining, such as the center webs 42 described above. Furthermore, the walls 41 can be formed at a further distance around the cavities 45 in order to avoid subsequent collisions during the joining here as well.

FIG. 1C shows the assembly subgroup 100.1 in a sectional view A-A. A contact connection 20 is fitted into the relevant center web 42 via the formed slot 25. The slot length and the height of the center web 42 can be adapted to one another in such a way that the holding frame 40 is held in a clamping manner by the contact connection 20 after a connection has been made of the contact connection 20 to the upper side 11 of the circuit carrier 10.

The enclosure 50 for the electronic module 100 is formed subsequently. For this purpose, the assembly subgroup 100.1 is arranged in an injection-molding tool 80, which has the outer shape of the enclosure 50. An injectable encapsulating material 51 is then injected into the injection-molding tool 80, in particular a molding material, wherein the enclosure 50 is then molded in a tool-dependent manner and the electrical circuit 31 is completely embedded in the encapsulating compound 51. The enclosure 50 is formed by a final solidification of the encapsulating compound 51.

In a first variant embodiment, the holding frame 40 is covered by the solidified encapsulating material 51 at most up to its wall end region 41b facing away from the upper side 11. For this purpose, the injection-molding tool 80 can rest in a sealing manner on the wall end region 41a during the injection-molding process, so that the encapsulating compound 51 is prevented from reaching the relevant contact region 21 of the contact connections 20. In this way, at least the contact regions 21 with the included press-fit zone 22 in each case are accordingly kept free of the encapsulating material 51. An electronic module 100 according to FIG. 2 is thus produced. The closing elements 28 can remain in place until, at the latest, the press-fit zones 22 make contact, before they are then removed.

In an alternative variant embodiment, the holding frame 40 is completely covered by the encapsulating compound 51 up to over its wall end region 41a facing away from the upper side 11 and over the contact regions 21, each comprising the press-fit zone 22, of the contact connections 20. Such a preliminary product 100.2 of the electronic module is shown in FIG. 1D.

Subsequently, in the region of the covered contact connections 20, each of the contact regions 21 with the comprised press-fit zones 22 is freed of the encapsulating compound 51 by means of a removal method. A laser removal method is particularly suitable for this purpose. By means of a laser 90, corresponding laser beams 91 are directed onto the contact regions 21 and the solidified encapsulating material 51 situated there is removed locally to a limited extent by the introduced laser energy, so that the electronic module 100 as shown in FIG. 2 is formed.

Alternatively, machining processes are possible, in which case attention must be paid to remaining or separated chip elements. The sealing elements 28 are then preferably also removed with the removal process.

In all embodiment variants, the cavity 45 is separated from the encapsulating material 51 by means of the holding frame 40.

FIG. 3A shows a sectional view of a detail of the electronic module 100 of FIG. 2 in the region of a contact connection 20 in a first possible embodiment, which also differs from the embodiment shown in FIG. 1A. The contact connection 20 has a flexible region 26 between a contact foot 23, 24 and the contact region 21. When contacting the press-fit zone 22 with a connection line 222 having a complementary design, the contact region 21 is designed to be yielding at least in the direction of the upper side 11 in order to limit joining forces F and/or to compensate for tolerances in this direction. Given flexible yielding up to a maximum distance x, the contact region 21 then sits on the underside in the holding frame 40 with integrally formed step shoulders, which then act as limiting stops 46.

FIG. 3B shows a sectional view of a detail of the electronic module 100 from FIG. 2 in the region of a contact connection 20, in a second possible embodiment. The embodiment differs from the one shown immediately before in that the cavity 45 on the side facing the upper side 11 is completely closed by a base region 47. The contact foot 23, 24, enclosed in a sealing manner by encapsulating material 51, is passed through the base region 47 toward the upper side 11, so that the contact foot is electrically connected to the corresponding contact point 15 on the upper side 11. Furthermore, the contact region 21 is already seated on corresponding limiting stops 46 before being joined to the connecting line 22. With the connection of the contact foot 23, 24, the holding frame 40 can be held in a clamped manner on the circuit carrier 10. In addition, the cavity 45 on the side of the holding frame 40 facing away from the upper side 11 is also closed by the contact region 21.

FIG. 3C shows a sectional view of a detail of the electronic module 100 from FIG. 2 in the region of a contact connection 20, in a third possible embodiment. This differs from the first and second embodiments described in that resilient latching elements 27 are integrally formed on the contact connection 20 in such a way that when the contact connection 20 is accommodated in the cavity 45 of the holding frame 40, the integrally formed latching element 27 is brought into operative connection with a complementary latching element 47 integrally formed on the holding frame 40, forming a latching connection R. The resilient latching element 27 integrally formed on the contact connection 20 remains in a pretensioned spring position after the contact foot 23, 24 has been connected to the corresponding contact point 15 on the upper side 11. The spring force F acting here presses the holding frame 40 against the circuit carrier 10 in a clamping manner.

There is a wide variety of possibilities for the arrangement and design of the mutually complementary latching elements 27, 47, so that the design shown here is not to be regarded as limiting. Furthermore, individual described realizations of the first to third embodiments described can be combined with one another, so that further possible embodiments are thereby mentioned. In addition to connecting the contact foot 23, 24 by means of a soldered, sintered or glued contact, it is possible to form the contact foot 23, 24 as a press-fit pin, which then engages in a corresponding recess in the circuit carrier 10. In general, the contact connection 20 is preferably formed as a shaped sheet metal part.

Furthermore, the descriptions also apply in the case of an embodiment of contact groups I, II in an arrangement that differs from the linear arrangement, in particular a circular arrangement.

1-15. (canceled)

16. An electronic module, comprising:
a circuit carrier including an electrical and/or electronic circuit which is completely embedded in an encapsulating compound, the encapsulating compound being a molding compound and forming an enclosure, and the circuit carrier including at least one electrically contactable external contact connection arranged on the enclosure and including at least one press-fit zone, wherein the contact connection is electrically connected to the electrical and/or electronic circuit on an upper side of the circuit carrier facing the press-fit zone and is exposed by the encapsulating compound at least in a region of the press-fit zone in the enclosure;
wherein the contact connection is accommodated in a cavity of a holding frame made of a plastic material, wherein the cavity is formed by a wall which runs around the contact connection in a closed manner and rests on the upper side of the circuit carrier and projects from the upper side of the circuit carrier in a direction of the press-fit zone, the wall separating the cavity from the encapsulating compound.

17. The electronic module according to claim 16, wherein the holding frame has at least two cavities, directly adjoining one another separated by a wall web, wherein in each of the at least two cavities a contact connection is arranged and formation of a defined connection schema of the electronic module.

18. The electronic module according to claim 17, wherein the connection schema includes at least two press-fit zones configured in a linear arrangement and/or in a circular arrangement.

19. The electronic module according to claim 16, wherein the contact connection has a connection foot which is in electrical contact with the upper side using a soldered, or sintered, or glued, or press-fit contact.

20. The electronic module according to claim 16, wherein the holding frame is configured as a positioning aid for a defined positioning of all accommodated contact connections relative to the upper side of the circuit carrier, wherein wall regions of the holding frame have defined limiting stops which restrict a positioning of all accommodated contact connections at least in a direction of a lateral extension of the upper side of the circuit carrier.

21. The electronic module according to claim 17, wherein the holding frame is configured as a positioning aid for a defined positioning of all accommodated contact connections relative to the upper side of the circuit carrier and for their defined positioning relative to one another, wherein wall regions of the holding frame have defined limiting stops which restrict positioning of all accommodated contact connections at least in a direction of a lateral extension of the upper side of the circuit carrier.

22. The electronic module according to claim 16, wherein the contact connection has a flexible region between a connection region with the upper side and the press-fit zone, wherein when a force is applied to the press-fit zone, the contact connection is configured to yield in the region of the press-fit zone, at least in a direction of the upper side, due to the flexible region, limited in its travel by a limiting stop integrally formed in the holding frame.

23. The electronic module according to claim 16, wherein an opening formed by a wall end region of the holding frame into the cavity on a side of the holding frame facing away from the upper side is closed by a contact region, having the press-fit zone, of the contact connection, in that the contact region rests on an edge of the wall end region.

24. The electronic module according to claim 16, wherein latching elements configured complementary to one another are integrally formed on the holding frame and on the contact connection, forming a latching connection such that the holding frame is held between the latching connection and the upper side of the circuit carrier, in a clamping manner.

25. The electronic module according to claim 16, wherein the contact connection is formed from a shaped sheet metal part.

26. The electronic module according to claim 16 wherein the press-fit zone is a recess which is a circular hole, and which is complementary to a press-fit head of a press-fit pin to be pressed into the recess.

27. A contact arrangement, comprising:
an electronic module, the electronic module including:
a circuit carrier including an electrical and/or electronic circuit which is completely embedded in an encapsulating compound, the encapsulating compound being a molding compound and forming an enclosure, and the circuit carrier including at least one electrically contactable external contact connection arranged on the enclosure and including at least one press-fit zone, wherein the contact connection is electrically connected to the electrical and/or electronic circuit on an upper side of the circuit carrier facing the press-fit zone and is exposed by the encapsulating compound at least in a region of the press-fit zone in the enclosure,
wherein the contact connection is accommodated in a cavity of a holding frame made of a plastic material, wherein the cavity is formed by a wall which runs around the contact connection in a closed manner and rests on the upper side of the circuit carrier and projects from the upper side of the circuit carrier in a direction of the press-fit zone, the wall separating the cavity from the encapsulating compound; and
a connecting line, which is in electrical contact with a contact connection of another electronic moduleor of an electrical component outside the electronic module, wherein a press-fit contact is formed between the connecting line which includes a press-fit pin, and the press-fit zone of the contact connection includes a recess formed to be complementary to the press-fit pin.

28. A method for forming an electronic module, the electronic module including:
a circuit carrier including an electrical and/or electronic circuit which is completely embedded in an encapsulating compound, the encapsulating compound being a molding compound and forming an enclosure, and the circuit carrier including at least one electrically contactable external contact connection arranged on the enclosure and including at least one press-fit zone, wherein the contact connection is electrically connected to the electrical and/or electronic circuit on an upper side of the circuit carrier facing the press-fit zone and is exposed by the encapsulating compound at least in a region of the press-fit zone in the enclosure,
wherein the contact connection is accommodated in a cavity of a holding frame made of a plastic material, wherein the cavity is formed by a wall which circumferentially surrounds the contact connection in a closed manner and rests on the upper side of the circuit carrier and projects from the upper side of the circuit carrier in a direction of the press-fit zone, the wall separating the cavity from the encapsulating compound;
the method comprising the following steps:
a) providing the circuit carrier;
b) arranging the at least one external contact connection of the electronic module on the upper side of the circuit carrier and connecting the the at least one external contact connection electrically to the electrical and/or electronic circuit forming a soldered or sintered or glued or press-fit contact;
c) forming an assembly subgroup by arranging the holding frame on the circuit carrier in such a way that a wall end region facing the upper side of the circuit carrier rests on the circuit carrier and the contact connection is accommodated within the cavity formed by the closed circumerential wall of the holding frame, so that the wall end region facing away from the upper side and a contact region, including the press-fit zone, of the contact connection project from the circuit carrier;
d) forming the enclosure of the electronic module using an injection-molding process by arranging the assembly subgroup within an injection-molding tool forming the enclosure, injecting an injectable encapsulating compound into the injection-molding tool, with molding of the enclosure and complete embedding of the electrical and/or electronic circuit within the encapsulating compound, demolding with subsequent solidification of the enclosure, wherein:
i. the holding frame is completely covered by the encapsulating compound up to over its wall end region facing away from the upper side and the contact region of the contact connection including the press-fit zone, and at least the press-fit zone is subsequently exposed from the encapsulating compound in the solidified enclosure by a laser removal process, or
ii. the holding frame is covered by the encapsulating compound at most up to its wall end region facing away from the upper side, whereby the contact connection is kept free of the encapsulating compound at least in the contact region including the press-fit zone.

29. The method according to claim 28, wherein, in a function of the holding frame as a positioning aid for all contact connections to be accommodated, method step c) is carried out before method step b), wherein the positioning of all contact connections then accommodated in a respective cavity is restricted at least in a direction of a lateral extension of the upper side of the circuit carrier by limiting stops defined in wall regions of the holding frame.

30. The method according to claim 28, wherein the contact region or the press-fit zone of the at least one contact connection is covered or closed by a closure element before method step d) in order to prevent direct penetration of the encapsulating compound into the press-fit zone or the cavity, the closure element being removed again during or after method step d).

31. The method according to claim 28, wherein a latching connection is formed by an accommodation of the at least one contact connection in the cavity of the holding frame, whereby the contact connection is held within the holding frame or the holding frame is held between the circuit carrier and the contact connection, in a force-loaded or clamping manner.
